(19) United States
(12) Patent Application Publication
(10) Pub. No.: US 2015/0075617 A1
(43) Pub. Date: Mar. 19, 2015

(54) HIGH-POWER AND HIGH RELIABILITY SOLAR MODULE

(71) Applicant: Changzhou Almaden Co., Ltd., Changzhou (CN)

(72) Inventors: Jinxi Lin, Changzhou (CN); Jinhan LIN, Changzhou (CN); Yuting LIN, Wufeng Township (TW); Chun Liang LIN, New Taipei City (TW)

(21) Appl. No.: 14/490,202

(22) Filed: Sep. 18, 2014

(30) Foreign Application Priority Data
Sep. 18, 2013 (CN) 201310430896.2

(51) Int. Cl. H01L 31/048

(52) U.S. Cl. CPC H01L 31/0488; H01L 31/0481
USPC 136/259

(57) ABSTRACT

The present application relates to a high-power solar module with high reliability and, more particularly, to a thin and light solar module with high efficiency and a long life. To resolve the aging problem occurring in a conventional back plate structure and the technical problem of low efficiency of the solar module caused by the excessively thin or thick embossed glass, the present invention therefore provides a solar module comprising a lower-layer tempered glass; a lower-layer adhesion layer; a solar cell; an upper-layer adhesion layer; a glass ball layer; and an upper-layer tempered glass. The present invention also provides a solar module comprising a lower-layer tempered glass; a lower-layer adhesion layer; a solar cell; an upper-layer adhesion layer; and an upper-layer tempered glass, wherein refraction particles are doped in the upper-layer adhesion layer, the lower-layer adhesion layer, or the two adhesion layers. The solar module of the present invention can effectively enhance the efficiency of the solar module.

### CROSS-REFERENCE TO RELATED APPLICATION

This Application claims priority to Chinese patent application number 201310430896.2, filed on Sep. 18, 2013 and the contents of which in its entirety are herein incorporated by reference.

### BACKGROUND OF THE INVENTION

1. Field of the Invention The present application relates to a high-power solar module with high reliability, and, more particularly, to a thin and light solar module with high efficiency and a long life.

2. Description of the Related Art

Currently, solar energy is the most popular environmentally friendly energy. Generally, solar energy is converted into electric energy by utilizing the photovoltaic effect of a solar cell.

A solar cell assembly is generally formed by combining a multilayered structure of embossed glass with a thickness of 3.2 mm/an adhesion layer/a photoelectric component/an adhesion layer/a solar energy back plate, and peripheral components such as an outer frame made of aluminum, a galvanized steel plate, wood or synthetic materials (such as polyethylene, polypropylene, or ethylene propylene rubber), a junction box, wires, and a storage battery. The glass used by the solar cell assembly needs to be tempered to increase its strength and durability. Glass embossing can make incoming sunlight produce light scattering to increase the length of a path that the sunlight passes in a module, which further increases the overall efficiency of the solar module. A solar energy back plate is mainly made of polyvinyl fluoride (for example, Tedlar® of the DuPont Company) structure. Under sunlight irradiation, the solar cell assembly outputs a certain working voltage and a certain working current through the photoelectrical effect.

However, a conventional back plate structure has an aging problem; as a result, a solar module rarely reaches the basic requirement of a 20-year service life. If the conventional back plate structure is replaced with embossed glass with a thickness of about 3.2 mm, the solar module may result in excessive thickness. However, if tempered glass of 2 mm is simply used, the efficiency of the solar module may be relatively low because the glass is excessively thin and there is no existing embossing technology for manufacturing the thin glass.

To solve the foregoing technical problems, the present application provides a solar module with high efficiency and high reliability.

### SUMMARY OF THE INVENTION

An objective of the present invention is to provide a solar module, comprising:
a lower-layer tempered glass;
a lower-layer adhesion layer, located above the lower-layer tempered glass;
a solar cell, located above the lower-layer adhesion layer;
an upper-layer adhesion layer, located above the solar cell;
a glass ball layer, located in or above the upper-layer adhesion layer, the lower-layer adhesion layer, or both the adhesion layers; and
an upper-layer tempered glass, located above the glass ball layer;
wherein the thickness of the tempered glass is from about 0.5 mm to about 2.5 mm.

Another objective of the present invention is to provide a solar module, comprising:
a lower-layer tempered glass;
a lower-layer adhesion layer, located above the lower-layer tempered glass;
a solar cell, located above the lower-layer adhesion layer;
an upper-layer adhesion layer, located above the solar cell;
an upper-layer tempered glass, located above the upper-layer adhesion layer;
wherein the thickness of the tempered glass is from about 0.5 mm to about 2.5 mm,
wherein refraction particles are doped in the upper-layer adhesion layer, the lower-layer adhesion layer, or both the adhesion layers, wherein the refraction particles have an optical refraction coefficient ranging from 1.3 to 2.5, and have a particle size ranging from 0.01 μm to 60 μm.

### BRIEF DESCRIPTION OF THE DRAWINGS

FIG. 1A is a schematic cross-sectional view of the solar module according to one embodiment of the present invention.

FIG. 1B is a schematic cross-sectional view of the solar module according to one embodiment of the present invention.

FIG. 1C is a schematic cross-sectional view of the solar module according to one embodiment of the present invention.

FIG. 1D is a schematic cross-sectional view of the solar module according to one embodiment of the present invention.

FIG. 2A is a schematic cross-sectional view of the solar module according to another embodiment of the present invention.

FIG. 2B is a schematic cross-sectional view of the solar module according to another embodiment of the present invention.

FIG. 2C is a schematic cross-sectional view of the solar module according to another embodiment of the present invention.

FIG. 2D is a schematic cross-sectional view of the solar module according to another embodiment of the present invention.

### DETAILED DESCRIPTION OF THE INVENTIONS

In this context, unless otherwise limited, a singular term (such as “a”) also includes a plural form thereof. In this context, all embodiments and exemplary terms (for example, “such as”) only aim at making the present invention more prominent and are not intended to limit the scope of the present invention; and terms in this specification should not be construed as implying that any component not claimed may form a necessary component for implementing the present invention.

An objective of the present invention is to provide a solar module, comprising:
a lower-layer tempered glass;
a lower-layer adhesion layer, located above the lower-layer tempered glass;
a solar cell, located above the lower-layer adhesion layer;
an upper-layer adhesion layer, located above the solar cell;
a glass ball layer, located in or above the upper-layer adhesion layer, the lower-layer adhesion layer, or both the adhesion layers; and
an upper-layer tempered glass, located above the glass ball layer;
wherein the thickness of the tempered glass is from about 0.5 mm to about 2.5 mm.

Another objective of the present invention is to provide a solar module, comprising:
a lower-layer tempered glass;
a lower-layer adhesion layer, located above the lower-layer tempered glass;
a solar cell, located above the lower-layer adhesion layer;
an upper-layer adhesion layer, located above the solar cell;
an upper-layer tempered glass, located above the upper-layer adhesion layer;
wherein the thickness of the tempered glass is from about 0.5 mm to about 2.5 mm,
wherein refraction particles are doped in the upper-layer adhesion layer, the lower-layer adhesion layer, or both the adhesion layers, wherein the refraction particles have an optical refraction coefficient ranging from 1.3 to 2.5, and have a particle size ranging from 0.01 μm to 60 μm.

The following further describes the components and the technical features of a solar module of the present invention.

A material of an adhesion layer for use in a solar cell module of the present invention is mainly used to fasten a photoelectric component of a solar cell and provide physical protection for the photoelectric component, for example, shock resistance or prevention of moisture damage. An adhesion layer for use in a solar cell assembly of the present invention can be any conventional material, comprising ethylene vinyl acetate (EVA), polyvinyl butyral (PVB), silica gel, and a thin film ionic polymer, for example, Dupont PV5400, where, currently, EVA is the most widely used material for an adhesion layer of a solar cell plane. EVA is a thermosetting resin that exhibits, after curing, high light transmission, heat resistance, low-temperature resistance, moisture resistance, weather resistance, and other characteristics, has good adherence with metal, glass and plastic, and also has a certain level of elasticity, shock resistance, and heat conductivity; therefore, it is an ideal material for an adhesion layer of the solar cell.

The solar cell in the solar cell module of the present invention is not specially limited and may be a solar cell of any form, for example, a crystalline silicon solar cell, a thin film solar cell, a dye-photosensitization solar cell, or the like.

The tempered glass for use in the present invention can be a novel physical tempered glass, which may be manufactured by treatment procedures such as aerodynamic heating and cooling. Specifically, this type of physical tempered glass may be made by performing heating in an aerodynamic-heating tempering furnace (for example, a flatbed tempering furnace produced by LiSEC corporation) at a temperature ranging from about 600° C. to about 750° C., preferably from 630° C. to about 700° C., and then performing rapid cooling by, for example, an air nozzle. The terminology “aerodynamic heating” herein refers to a process of transferring heat to an object by using high temperature gas that is generated when the object performs a relative movement with air or another gas at a high velocity, or a process of transferring heat to an object by using air/gas floatation to replace conventional rolling transport in a heating furnace or tempering furnace. When glass is tempered in the aerodynamic heating manner, the glass does not directly contact the tempering furnace, and therefore the glass is not deformed, which can be suitable for relatively thin glass. For a more detailed method for manufacturing the physical tempered glass, reference may be made to the content of Chinese Patent Application No. 201110198526.1. In particular, the tempered glass suitable to the present invention is a transparent ultrathin tempered glass with a thickness from 0.5 mm to 2.5 mm. The physical tempered glass applicable to the present invention has compressive strength of about 120 MPa to about 300 MPa, preferably about 150 MPa to about 250 MPa, bending strength of about 120 MPa to about 300 MPa, preferably about 150 MPa to about 250 MPa, and tensile strength of about 90 MPa to about 180 MPa, preferably about 100 MPa to about 150 MPa.

A particle size of a glass ball in a glass ball layer applicable to the present invention ranges from 0.01 μm to 20 μm, where the content of the glass ball in the adhesion layer is from 0.01% to 0.1% of the total weight of the adhesion layer. If the content of the glass ball in the adhesion layer is lower than 0.01%, it is difficult to improve a light scattering rate; and if the content is higher than 0.1%, it may also cause excessive light scattering, whereby the light scattering rate decreases rather than increases.

The refraction particles applicable to the present invention have an optical refraction coefficient ranging from 1.3 to 2.5, and have a particle size ranging from 0.01 μm to 60 μm. A material of the refraction particle may be selected from MgF₂, SiO₂, SiNₓ, TiO₂, ZnO, and a combination thereof.

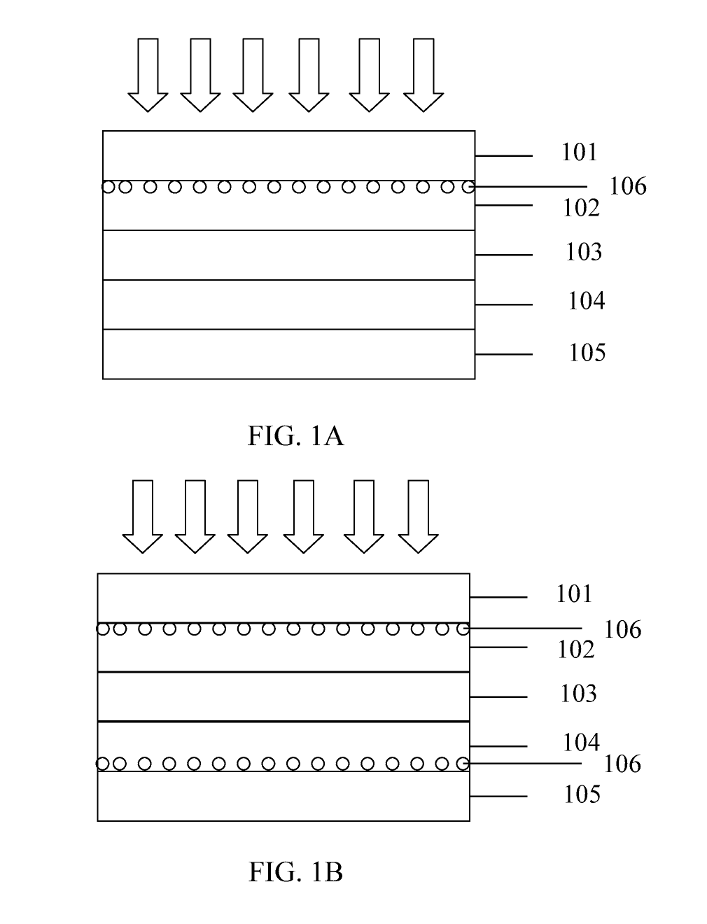

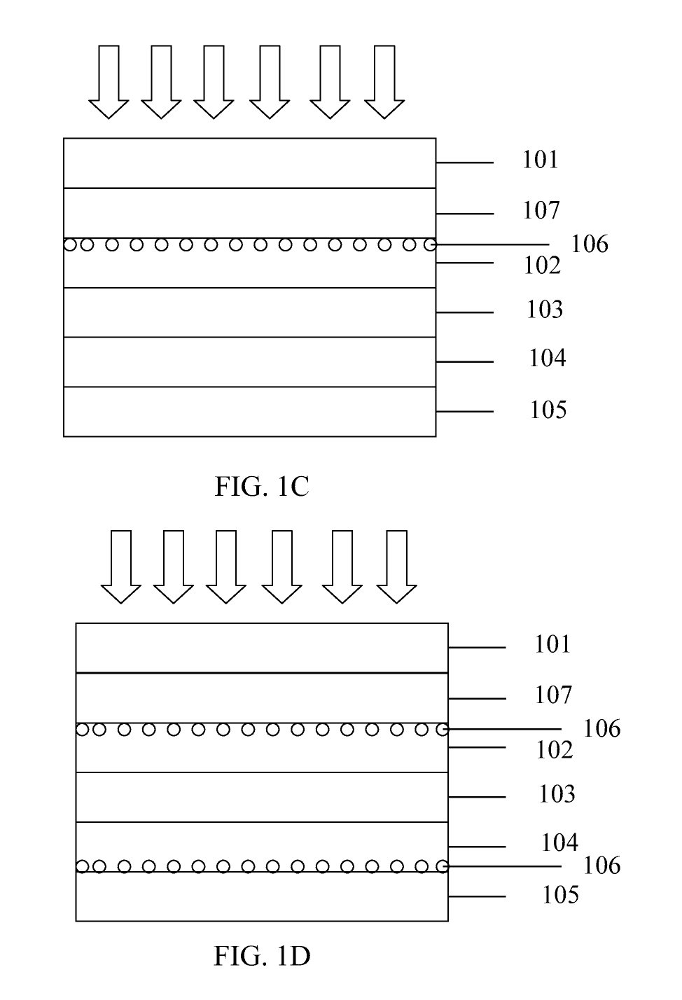

### FIGS. 1A to 1D

As shown in FIG. 1A, in a specific embodiment of the present invention, an arrowhead indicates an emitting direction of illuminating light, 101 indicates an upper-layer tempered glass, 102 indicates an upper-layer adhesion layer, 103 indicates a solar cell, 104 indicates a lower-layer adhesion layer, 105 indicates a lower-layer tempered glass, and 106 indicates a glass ball layer, where a thickness of the tempered glass ranges from about 0.5 mm to about 2.5 mm.

In a specific embodiment of the present invention, the adhesion layer is selected from ethylene vinyl acetate (EVA), polyvinyl butyral (PVB), silica gel, and a thin film ionic polymer, for example, Dupont PV5400.

In a specific embodiment of the present invention, the physical tempered glass has compressive strength of about 120 MPa to about 300 MPa, preferably about 150 MPa to about 250 MPa, bending strength of about 120 MPa to about 300 MPa, preferably about 150 MPa to about 250 MPa, and tensile strength of about 90 MPa to about 180 MPa, preferably about 100 MPa to about 150 MPa.

In a specific embodiment of the present invention, the particle size of the glass balls in the glass ball layer ranges from 0.01 μm to 20 μm.

In a specific embodiment of the present invention, the content of the glass ball in the glass ball layer is from 0.01% to 0.1% of the total weight of the adhesion layer.

In a specific embodiment of the present invention, the glass ball layer is located between the upper-layer adhesion layer and the upper-layer tempered glass.

In a specific embodiment of the present invention, the glass ball layer is located between the lower-layer adhesion layer and the lower-layer tempered glass.

In a specific embodiment of the present invention, the glass ball layers are located between the upper-layer adhesion layer and the upper-layer tempered glass as well as between the lower-layer adhesion layer and the lower-layer tempered glass.

As shown in FIG. 1B and FIG. 1D, in a specific embodiment of the present invention, a photoelectric component in a solar cell assembly may be a double-faced photoelectric component, for example, HIT Double® of the SANYO Company, so as to fully utilize optical energy reflected from a light collection chamber to the photoelectric component. As shown in FIG. 1D, a glass ball layer 106 may be additionally covered on a lower-layer adhesion layer 104.

As shown in FIG. 1C and FIG. 1D, in a specific embodiment of the present invention, when the glass ball layer is located above the upper-layer adhesion layer, the solar module further comprises a top adhesion layer 107, which is located between the glass ball layer and the upper-layer tempered glass, wherein the top adhesion layer 107 is selected from ethylene vinyl acetate (EVA), polyvinyl butyral (PVB), silica gel, and a thin film ionic polymer, for example, Dupont PV5400.

In a specific embodiment of the present invention, the glass ball layer is doped in the adhesion layer.

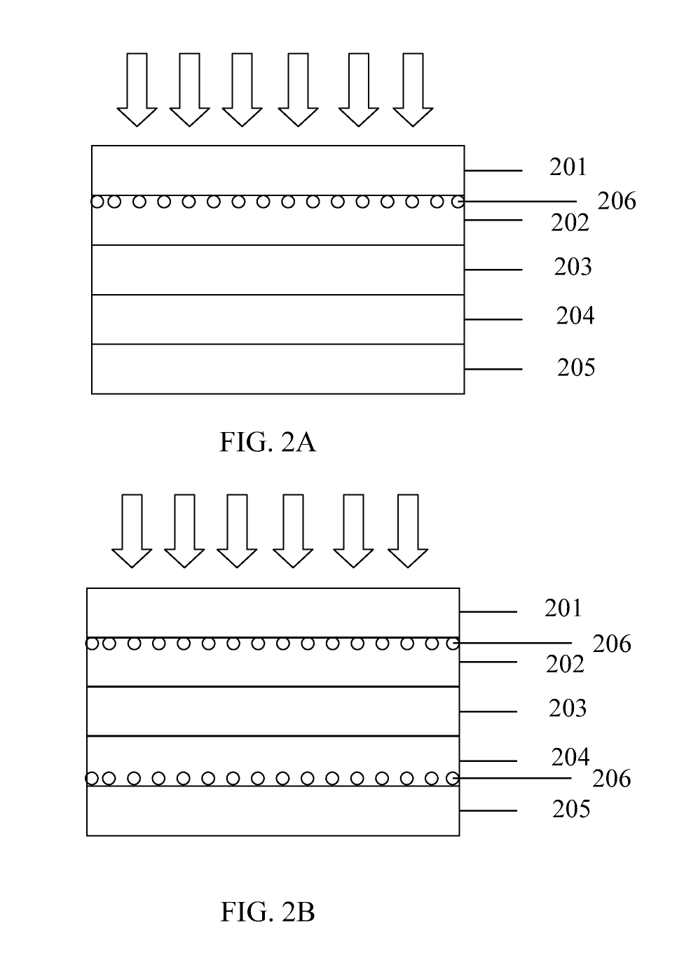

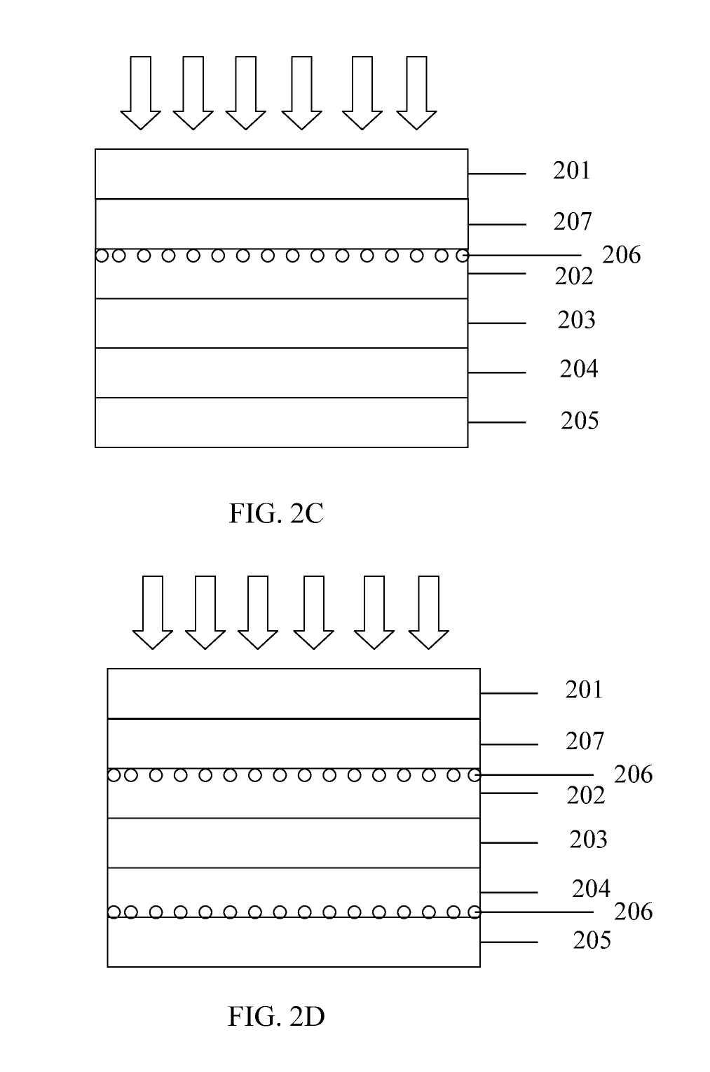

### FIGS. 2A to 2D

As shown in FIG. 2A, in another specific embodiment of the present invention, an arrowhead indicates an emitting direction of illuminating light, 201 indicates an upper-layer tempered glass, 202 indicates an upper-layer adhesion layer, 203 indicates a solar cell, 204 indicates a lower-layer adhesion layer, 205 indicates a lower-layer tempered glass, and 206 indicates refraction particles, where a thickness of the tempered glass ranges from about 0.5 mm to about 2.5 mm.

In another specific embodiment of the present invention, the adhesion layer is selected from ethylene vinyl acetate (EVA), polyvinyl butyral (PVB), silica gel, and a thin film ionic polymer, for example, Dupont PV5400.

In another specific embodiment of the present invention, the tempered glass has compressive strength of about 120 MPa to about 300 MPa, preferably about 150 MPa to about 250 MPa, bending strength of about 120 MPa to about 300 MPa, preferably about 150 MPa to about 250 MPa, and tensile strength of about 90 MPa to about 180 MPa, preferably about 100 MPa to about 150 MPa.

In yet another specific embodiment of the present invention, the refraction particles have an optical refraction coefficient ranging from 1.3 to 2.5, and have a particle size ranging from 0.01 μm to 60 μm.

In yet another specific embodiment of the present invention, the content of the refraction particles in the adhesion layer is from 0.01% to 0.1% of the total weight of the adhesion layer.

In yet another specific embodiment of the present invention, the material of the refraction particles is selected from MgF₂, SiO₂, SiNₓ, TiO₂, ZnO, and a combination thereof.

As shown in FIGS. 2B and 2D, in a specific embodiment of the present invention, a photoelectric component in a solar cell assembly may be a double-faced photoelectric component, for example, HIT Double® of the SANYO Company, so as to fully utilize optical energy reflected from a light collection chamber to the photoelectric component, and a refraction particle layer 206 may be additionally covered on a lower-layer adhesion layer 204.

As shown in FIGS. 2C and 2D, in a specific embodiment of the present invention, the solar module further comprises a top adhesion layer 207, which is located between the refraction particles and the upper-layer tempered glass, wherein the top adhesion layer 207 is selected from ethylene vinyl acetate (EVA), polyvinyl butyral (PVB), silica gel, and a thin film ionic polymer, for example, Dupont PV5400.

In a specific embodiment of the present invention, the refraction particles are doped between the upper-layer adhesion layer and the upper-layer tempered glass.

In a specific embodiment of the present invention, the refraction particles are doped between the lower-layer adhesion layer and the lower-layer tempered glass.

In a specific embodiment of the present invention, the refraction particles are doped between the upper-layer adhesion layer and the upper-layer tempered glass as well as between the lower-layer adhesion layer and the lower-layer tempered glass.

### EXAMPLES

The following embodiment further describes the present invention, and is not intended to limit the scope of the present invention. Any variation and change obtained by a person skilled in the art without departing from the spirit of the present invention shall fall within the scope of the present invention.

### Example 1

### Solar Module A1

Its architecture is: tempered glass of 2 mm/a glass ball layer/EVA of 0.2 mm/60-series solar cells of 0.2 mm (60 solar cells with 17.4% efficiency of the WitsView)/EVA of 0.2 mm/tempered glass of 2 mm.

### Example 2

### Solar Module A2

Its architecture is: tempered glass of 2 mm/EVA of 0.4 mm and glass balls/60-series solar cells of 0.2 mm (60 solar cells with 17.4% efficiency of the WitsView)/EVA of 0.2 mm/tempered glass of 2 mm.

### Reference Example 1

### Solar Module A3

Its architecture is: tempered glass of 2 mm/EVA of 0.2 mm/60-series solar cell of 0.2 mm (60 solar cells with 17.4% efficiency of the WitsView)/EVA of 0.2 mm/tempered glass of 2 mm

A material of glass balls in the solar modules A1 and A2 is SiO₂ having a circular shape, a particle size ranging from 0.01 μm to 60 μm, and a weight ratio concentration between the glass ball and the EVA as 0.2 wt %.

After module efficiency measurement, power is measured by using a sunlight simulator of the Pasan sun simulator 3C. The efficiency of the solar module A3 in reference example 1 without adding glass balls is 235 W, the efficiency of the solar module A1 with a glass ball layer added is 240 W, and the efficiency of the solar module A2 is 239.5 W.

It can be known from the result of the above experiments that adding a glass ball layer to a solar module can effectively improve the efficiency of the solar module.

What is claimed is:

1. A solar module, comprising:
a lower-layer tempered glass;
a lower-layer adhesion layer, located above the lower-layer tempered glass;
a solar cell, located above the lower-layer adhesion layer;
an upper-layer adhesion layer, located above the solar cell;
a glass ball layer, located in or above the upper-layer adhesion layer, the lower-layer adhesion layer, or both the adhesion layers; and
an upper-layer tempered glass, located above the glass ball layer;
wherein the thickness of the tempered glass is from about 0.5 mm to about 2.5 mm.

2. The solar module according to claim 1, wherein the adhesion layer is selected from ethylene vinyl acetate (EVA), polyvinyl butyral (PVB), silica gel, and a thin film ionic polymer.

3. The solar module according to claim 1, wherein the tempered glass has compressive strength of about 120 MPa to about 300 MPa, bending strength of about 120 MPa to about 300 MPa, and tensile strength of about 90 MPa to about 180 MPa.

4. The solar module according to claim 1, wherein the glass ball in the glass ball layer has a particle size ranging from 0.01 μm to 60 μm.

5. The solar module according to claim 1, wherein the content of the glass ball in the glass ball layer is from 0.01% to 0.1% of the total weight of the adhesion layer.

6. The solar module according to claim 1, wherein the glass ball layer is doped in the adhesion layer.

7. The solar module according to claim 1, wherein when the glass ball layer is located above the upper-layer adhesion layer, the solar module further comprises a top adhesion layer located between the glass ball layer and the upper-layer tempered glass.

8. The solar module according to claim 7, wherein the top adhesion layer is selected from ethylene vinyl acetate (EVA), polyvinyl butyral (PVB), silica gel, and a thin film ionic polymer.

9. The solar module according to claim 1, wherein the glass ball layer is located between the upper-layer adhesion layer and the upper-layer tempered glass; between the lower-layer adhesion layer and the lower-layer tempered glass; or both between the upper-layer adhesion layer and the upper-layer tempered glass and between the lower-layer adhesion layer and the lower-layer tempered glass.

10. A solar module comprising:
a lower-layer tempered glass;
a lower-layer adhesion layer, located above the lower-layer tempered glass;
a solar cell, located above the lower-layer adhesion layer;
an upper-layer adhesion layer, located above the solar cell; and
an upper-layer tempered glass, located above the upper-layer adhesion layer;
wherein the thickness of the tempered glass is from about 0.5 mm to about 2.5 mm, wherein refraction particles are doped in the upper-layer adhesion layer, the lower-layer adhesion layer, or both the adhesion layers, wherein the refraction particles have an optical refraction coefficient ranging from 1.3 to 2.5, and have a particle size ranging from 0.01 μm to 60 μm.

11. The solar module according to claim 10, wherein the adhesion layer is selected from ethylene vinyl acetate (EVA), polyvinyl butyral (PVB), silica gel, and a thin film ionic polymer.

12. The solar module according to claim 10, wherein the tempered glass has compressive strength of about 120 MPa to about 300 MPa, bending strength of about 120 MPa to about 300 MPa, and tensile strength of about 90 MPa to about 180 MPa.

13. The solar module according to claim 10, wherein the material of the refraction particle is selected from MgF₂, SiO₂, SiNₓ, TiO₂, ZnO, and a combination thereof.

14. The solar module according to claim 10, further comprising a top adhesion layer located between the refraction particles and the upper-layer tempered glass.

15. The solar module according to claim 10, wherein refraction particles are doped between the lower-layer adhesion layer and the lower-layer tempered glass, wherein the refraction particles have an optical refraction coefficient ranging from 1.3 to 2.5, and have a particle size ranging from 0.01 μm to 60 μm, and wherein the material of the refraction particle is selected from MgF₂, SiO₂, SiNₓ, TiO₂, ZnO, and a combination thereof.

16. The solar module according to claim 10, wherein the content of the refraction particles in the adhesive layer is from 0.01% to 0.1% of the total weight of the adhesion layer.

17. The solar module according to claim 14, wherein the content of the refraction particles in the adhesive layer is from 0.01% to 0.1% of the total weight of the adhesion layer.

18. The solar module according to claim 10, wherein the refraction particles are doped between the upper-layer adhesion layer and the upper-layer tempered glass; between the lower-layer adhesion layer and the lower-layer tempered glass; or both between the upper-layer adhesion layer and the upper-layer tempered glass and between the lower-layer adhesion layer and the lower-layer tempered glass.
